(19) United States
(12) Patent Application Publication
(10) Pub. No.: US 2021/0312979 A1
(43) Pub. Date: Oct. 7, 2021

(54) Read Circuitry for Resistive Change Memories

(71) Applicant: Infineon Technologies AG, Neubiberg (DE)

(72) Inventors: Wolf Allers, Muenchen (DE); Jan Otterstedt, Unterhaching (DE); Christian Peters, Vaterstetten (DE)

(21) Appl. No.: 17/218,373

(22) Filed: Mar. 31, 2021

(30) Foreign Application Priority Data
Apr. 3, 2020 (DE) 102020109378.0

(51) Int. Cl. G11C 13/00; G11C 11/16

(52) U.S. Cl. CPC G11C 13/004; G11C 13/0004; G11C 11/1673; G11C 11/1697; G11C 13/003; G11C 11/1659; G11C 13/0038; G11C 13/0011

(57) ABSTRACT

Read circuitry for a memory cell of a resistive change memory is suggested, wherein a signal of a bit-line that is connected to the memory cell is compared with a reference signal, and wherein the reference signal is determined based on a first dummy circuit that determines a leakage current of memory cells addressed by the bit-line. Also, a corresponding method is provided.

### TECHNICAL FIELD

Embodiments of the present invention relate to resistive change memories, which may comprise RRAM (resistive random-access memory), MRAM (magnetoresistive random-access memory), PCRAM (phase-change random-access memory) and CBRAM (conductive-bridging random-access memory).

### BACKGROUND

Resistive change memories suffer from a relatively small read window.

### SUMMARY

The objective is to improve existing solutions in particular to read RRAM cells with an improved accuracy.

The examples suggested herein may in particular be based on at least one of the following solutions. In particular combinations of the following features could be utilized in order to reach a desired result. The features of the method could be combined with any feature(s) of the device, apparatus or system or vice versa.

A read circuitry is suggested for a memory cell of a resistive change memory,

wherein a signal of a bit-line that is connected to the memory cell is compared with a reference signal,

wherein the reference signal is determined based on a first dummy circuit that determines a leakage current of memory cells addressed by the bit-line.

According to an embodiment, the resistive change memory comprises at least one of the following:

an RRAM,

a PCRAM,

an MRAM,

a CBRAM.

According to an embodiment, the first dummy circuit comprises a first reference bit-line that is connected to a first reference source-line via several dummy cells, wherein each dummy cell comprises a MOSFET but no resistive change memory element, wherein the MOSFET of the dummy cell is short-circuited.

Hence, each dummy cell of the first dummy circuit contributes to the overall leakage current.

According to an embodiment, the first dummy circuit comprises a number of dummy cells that corresponds to the number of memory cells addressed by the bit-line.

According to an embodiment, the first reference bit-line corresponds to the bit-line.

According to an embodiment, the reference signal is determined based on a second dummy circuit that determines a cell reference current that is based on a voltage drop in a read path.

According to an embodiment, the read path corresponds to a read path of the actual memory cell that is read.

According to an embodiment, the second dummy circuit comprises a second reference bit-line that is connected to a second reference source-line via several dummy cells, wherein each dummy cell comprises a MOSFET but no resistive change memory element, wherein only one MOSFET of the dummy cells is selected and the remaining MOSFETs of the dummy cells are unselected.

According to an embodiment, the memory cells of the resistive change memory are arranged in a functional matrix structure.

Also, a method is provided for accessing a memory cell of a resistive change memory comprising:

comparing a signal of a bit-line with a reference signal, wherein the bit-line is connected to the memory cell,

determining the reference signal based on a first dummy circuit that determines a leakage current of memory cells addressed by the bit-line.

According to an embodiment, the first dummy circuit comprises a first reference bit-line that is connected to a first reference source-line via several dummy cells, wherein each dummy cell comprises a MOSFET but no resistive change memory element, wherein the MOSFET of the dummy cell is short-circuited.

According to an embodiment, the reference signal is determined based on a second dummy circuit that determines a cell reference current that is based on a voltage drop in a read path.

According to an embodiment, the second dummy circuit comprises a second reference bit-line that is connected to a second reference source-line via several dummy cells, wherein each dummy cell comprises a MOSFET but no resistive change memory element, wherein only one MOSFET of the dummy cells is selected and the remaining MOSFETs of the dummy cells are unselected.

### BRIEF DESCRIPTION OF THE DRAWINGS

Embodiments are shown and illustrated with reference to the drawings. The drawings serve to illustrate the basic principle, so that only aspects necessary for understanding the basic principle are illustrated. The drawings are not to scale. In the drawings the same reference characters denote like features.

FIG. 1 shows an exemplary diagram visualizing sensing a current of a selected cell within an array of cells of an RRAM memory;

FIG. 2 shows an exemplary diagram that allows determining a reference signal that is based on a leakage current and a cell current reference that is based on a voltage drop in a read path of a memory cell; and

FIG. 3 shows an exemplary circuit that may be used as a variable resistor block.

### DETAILED DESCRIPTION

Examples described herein in particular refer to leakage compensation and reference approximation in RRAM read circuits. This may in particular be applicable in the area of sense amplifier design for RRAM circuits.

RRAM cells store data in a resistive state. In an exemplary scenario, a range below 6 kOhm corresponds to a logical state 1 and a range above 8 kOhm corresponds to a logical state 0. As the resulting read window may cover merely a range between 20% and 30% of the available range of potential values, the sensing may preferably be rather accurate.

The cell state of the RRAM cell may be read by applying a low voltage of a few hundred millivolts to a selected bit-line (BL) of the memory array. The resulting current is then either directly compared to an external reference current, or to a reference resistance array.

Because of the narrow read window, parasitic effects impeding the accuracy of the sensing result may be of high importance. The following detrimental effects may in particular impair the sensing results:

Leakage currents within the memory array.

A voltage drop resulting from resistances and other resistive elements that are part of the electrical read path.

The measured current is the sum of the (desired) selected cell current I_{cell} and leakage currents Iₗₑₐₖ that flow through all unselected cells. It is noted that the count of unselected cell may be large, e.g., more than 1000 cells.

The cell current I_{cell} is proportional to the V_{cell} voltage Veen, which is reduced with regard to a bit-line voltage V_{BL} because of a voltage drop over the bit-line BL, a select-line SL and a select transistor.

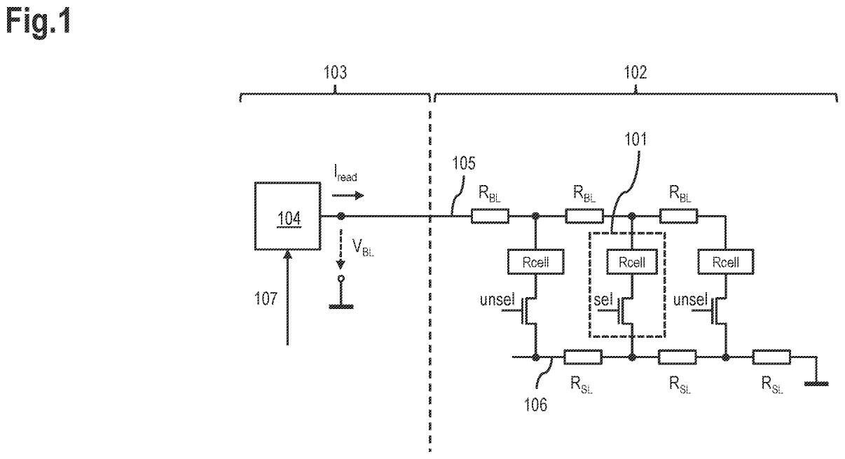

FIG. 1 shows an exemplary diagram visualizing sensing a cell current I_{cell} of a selected (resistive memory) cell 101 within an array 102 of (resistive memory) cells.

A periphery 103 is arranged separate to the array 102, wherein the periphery 103 comprises a sense amplifier 104 that is connected via a bit-line 105 to the array 102. A source-line 106 connects the array 102 to ground.

The sense amplifier 104 compares a read current I_{read} vs. a reference current. The reference current is supplied via a reference signal 107.

The bit-line 105 is represented by several resistors R_{BL} indicating a voltage drop that is associated with a portion of the bit-line 105. Accordingly, the source-line 106 is represented by several resistors R_{SL} indicating a voltage drop that is associated with a portion of the source-line 106.

Each of the cells of the array 102 comprises a resistive element (Rcell) and an electronic switch (MOSFET) that utilizes a word-line (driving the gate of the MOSFET) to select (or unselect) the respective memory cell of the array 102. In the scenario shown in FIG. 1, the cell 101 is selected and the remaining cells of the array 102 are unselected.

When the cell 101 is selected, two effects cause a distortion of the expected cell current:
(1) the actual voltage applied to the RRAM cell is reduced by voltage drops over peripheral transistors as well as the bit-line 105 and the source-line 106, hence increasing the effective total resistance and decreasing the cell current;
(2) the unselected remaining cells of the array 102 contribute to the current detected by the sense amplifier 104.

Hence, the read current I_{read} determined by the sense amplifier 104 may be roughly summarized as

I_{read}=(N−1)·Iₗₑₐₖ+I_{cell},

wherein N indicates the number of memory cells of the array 102 and Leak indicates a leakage current that stems from the cells between the bit-line 105 and the word-line 106 other than the selected cell 101.

It is in particular suggested to provide an external reference, e.g., a current source and/or an adjustable resistance value, which is a structure of the array thereby including parasitic effects. This can be achieved by providing dummy circuits without actual resistive elements. For example, dummy bit-lines (and/or dummy source-lines) may be used, which may be present anyway around stitching and break lines.

This approach bears the advantage that the parasitic effects are based on real physical structures and therefore provide a high accuracy with regard to, e.g., temperature-dependency, voltages and process parameters. In other words, the physical effects that impact the dummy lines have (substantially) the same influence on the actual memory cell to be read and are therefore comparable to the actual memory cells and read path(s). This allows considering the effects of the dummy elements and based thereon determine a corrected read current.

Another advantage is that this solution does not waste much area of the memory array, as only a few reference bit-lines/source-lines are needed.

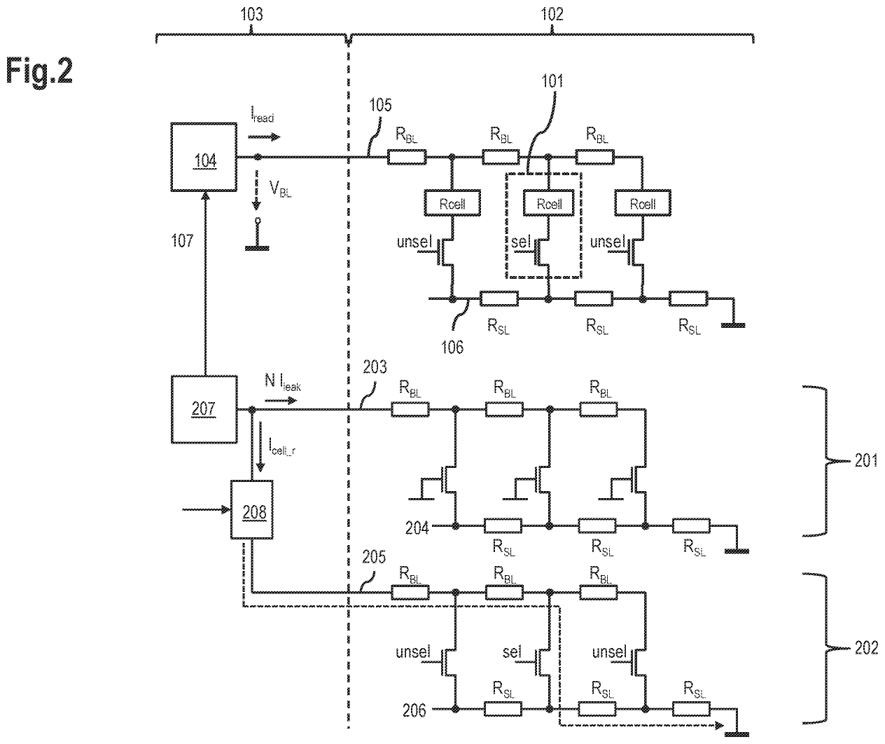

FIG. 2 shows an exemplary diagram that allows determining a reference signal 107 that is based on a leakage current N·Iₗₑₐₖ and a cell current reference I_{cell_r}, that is based on a voltage drop in a read path of a memory cell.

In an exemplary embodiment, two reference lines 201 and 202, each comprising a reference bit-line 203, 205 and a reference source-line 204, 206, are used to compile the reference signal 107, e.g., via a reference generator 207.

The reference line 201 comprises the reference bit-line 203 and the reference source-line 204, which are connected via dummy cells, each dummy cell comprising a MOSFET with its gate connected to ground but no actual resistive change memory element. It is noted that there may be (N−1) or N dummy cells.

The reference line 201 is thus used to provide a leakage current that is comparable to the memory cells that are addressed by the bit-line.

The reference line 202 comprises the reference bit-line 205 and the reference source-line 206, which are connected via N dummy cells, each dummy cell comprising only a MOSFET and no resistive change memory element, wherein N are unselected or (N−1) of the dummy cells are unselected and one dummy cell is selected.

“Unselected” may correspond to applying a voltage amounting to 0V to the respective gates. “Selected” may correspond to applying a voltage amounting to 1.3V to the gate of the particular dummy cell that corresponds to the actual selected cell 101. The selected/unselected voltage is provided via word-lines.

It is noted that the selected dummy cell and the selected cell 101 may be adjacent to each other in the memory array.

The reference line 202 thus generates a voltage drop that is comparable to the voltage drop of the actual read path of the memory cell 101.

Hence, the reference generator is supplied with N times the leakage current Iₗₑₐₖ by the first reference line 201 and by a voltage drop of the read path by the reference line 202, resulting in a reduced reference current I_{cell_r}.

As the state of the resistive memory cell is defined by its resistance value, a variable resistor block 208 may serve as reference. Such variable resistor block 208 may comprise a set of in-series matching resistors, which could be switched on or off by level signals. They add up to a total resistance as a reference to the RRAM cells.

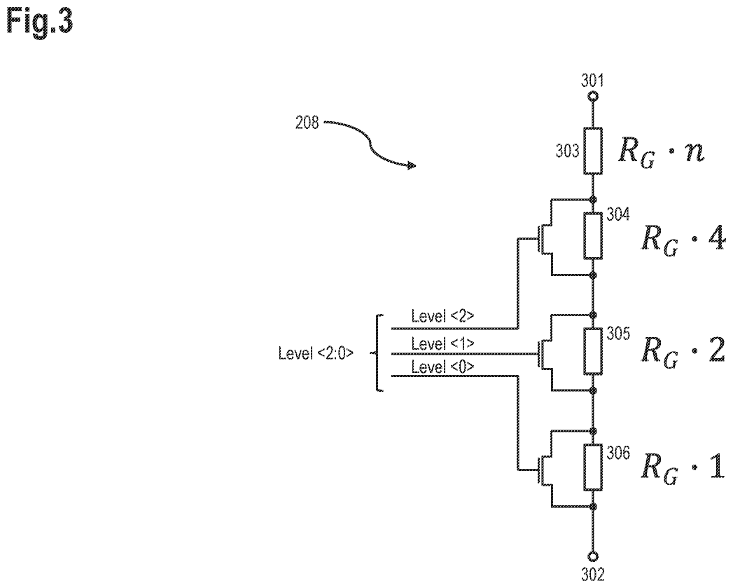

FIG. 3 shows an exemplary circuit that may be used as a variable resistor block 208. A node 301 can be connected to the reference generator 207 and a node 302 can be connected to the bit-line 205 of the reference line 202. As an alternative, the node 302 may be connected to ground.

The circuit of FIG. 3 further comprises a series-connection of four resistors 303 to 306, wherein the resistors 304 to 306 may be optionally short-circuited via a MOSFET. Hence, FIG. 3 shows three MOSFETs which are controlled via a signal applied to their respective gates. If the gate of a MOSFET is activated, it short-circuits its associated resistor thereby reducing the series connection of the resistors 303 to 306 by a value that corresponds to the resistance of the short-circuited resistor.

Three signals Level<0>, Level<1> and Level<2> can be used to separately toggle (i.e. activate or deactivate) each of the resistors 304 to 306 in the series connection of resistors. As a result, the series connection comprises resistor 303 in combination of any (or none) of the resistors 304 to 306.

In the example shown, the resistors 303 to 306 have the following resistance values:

resistor 303: R_{G}·n,

resistor 304: R_{G}·4,

resistor 305: R_{G}·2, and

resistor 306: R_{G}·1.

The input signals driving the gates of the MOSFETs shown in FIG. 3 can be provided by a three-bit-bus. These three level signals allow for 2³=8 combinations to adjust resistance values of the series connection. Using the resistance values indicated above allows setting any of the resistance values from 1 R_{G} to 7 R_{G} via the resistors 304 to 306.

Hence, this approach allows determining the voltage drop over the read path caused by the leakage current of the memory cells via dummy cells connected to a reference line 201; and voltage drop over the read path caused by a reference current of one selected dummy cell connected to a reference line (indicated by the reference line 202).

The reference generator 207 supplies the reference signal 107 based on the leakage current and the cell reference current to the sense amplifier 104, which allows correcting the read current.

Although various exemplary embodiments of the invention have been disclosed, it will be apparent to those skilled in the art that various changes and modifications can be made which will achieve some of the advantages of the invention without departing from the spirit and scope of the invention. It will be obvious to those reasonably skilled in the art that other components performing the same functions may be suitably substituted. It should be mentioned that features explained with reference to a specific figure may be combined with features of other figures, even in those cases in which this has not explicitly been mentioned. Further, the methods of the invention may be achieved in either all software implementations, using the appropriate processor instructions, or in hybrid implementations that utilize a combination of hardware logic and software logic to achieve the same results. Such modifications to the inventive concept are intended to be covered by the appended claims.

What is claimed is:

1. Read circuitry for a memory cell of a resistive change memory,
wherein a signal of a bit-line that is connected to the memory cell is compared with a reference signal,
wherein the reference signal is determined based on a first dummy circuit that determines a leakage current of memory cells addressed by the bit-line.

2. The read circuitry of claim 1, wherein the resistive change memory comprises at least one of the following:
an RRAM;
a PCRAM;
an MRAM; and
a CBRAM.

3. The read circuitry of claim 1, wherein the first dummy circuit comprises a first reference bit-line that is connected to a first reference source-line via several dummy cells, wherein each dummy cell comprises a MOSFET but no resistive change memory element, and wherein the MOSFET of the dummy cell is short-circuited.

4. The read circuitry of claim 3, wherein the first dummy circuit comprises a number of dummy cells that corresponds to the number of memory cells addressed by the bit-line.

5. The read circuitry of claim 3, wherein the first reference bit-line corresponds to the bit-line.

6. The read circuitry of claim 5, wherein the read path corresponds to a read path of the actual memory cell that is read.

7. The read circuitry of claim 1, wherein the reference signal is determined based on a second dummy circuit that determines a cell reference current that is based on a voltage drop in a read path.

8. The read circuitry of claim 7, wherein the second dummy circuit comprises a second reference bit-line that is connected to a second reference source-line via several dummy cells, wherein each dummy cell comprises a MOSFET but no resistive change memory element, and wherein only one MOSFET of the dummy cells is selected and the remaining MOSFETs of the dummy cells are unselected.

9. The read circuitry of claim 1, wherein the memory cells of the resistive change memory are arranged in a functional matrix structure.

10. A method for accessing a memory cell of a resistive change memory, the method comprising:
comparing a signal of a bit-line with a reference signal, wherein the bit-line is connected to the memory cell; and
determining the reference signal based on a first dummy circuit that determines a leakage current of memory cells addressed by the bit-line.

11. The method of claim 10, wherein the first dummy circuit comprises a first reference bit-line that is connected to a first reference source-line via several dummy cells, wherein each dummy cell comprises a MOSFET but no resistive change memory element, and wherein the MOSFET of the dummy cell is short-circuited.

12. The method of claim 10, wherein the reference signal is determined based on a second dummy circuit that determines a cell reference current that is based on a voltage drop in a read path.

13. The method of claim 12, wherein the second dummy circuit comprises a second reference bit-line that is connected to a second reference source-line via several dummy cells, wherein each dummy cell comprises a MOSFET but no resistive change memory element, and wherein only one MOSFET of the dummy cells is selected and the remaining MOSFETs of the dummy cells are unselected.

14. Read circuitry for a memory cell of a resistive change memory, the read circuitry comprising:
a sense amplifier configured to compare a signal of a bit-line that is connected to the memory cell with a reference signal; and
a first dummy circuit configured to determine a leakage current of memory cells addressed by the bit-line,
wherein the reference signal is determined based on the first dummy circuit.

15. The read circuitry of claim 14, wherein the resistive change memory comprises at least one of the following:
an RRAM;
a PCRAM;
an MRAM; and
a CBRAM.

16. The read circuitry of claim 14, wherein the first dummy circuit comprises a first reference bit-line that is connected to a first reference source-line via several dummy cells, wherein each dummy cell comprises a MOSFET but no resistive change memory element, and wherein the MOSFET of the dummy cell is short-circuited.

17. The read circuitry of claim 16, wherein the first dummy circuit comprises a number of dummy cells that corresponds to the number of memory cells addressed by the bit-line.

18. The read circuitry of claim 14, wherein the reference signal is determined based on a second dummy circuit that determines a cell reference current that is based on a voltage drop in a read path.

19. The read circuitry of claim 18, wherein the second dummy circuit comprises a second reference bit-line that is connected to a second reference source-line via several dummy cells, wherein each dummy cell comprises a MOSFET but no resistive change memory element, and wherein only one MOSFET of the dummy cells is selected and the remaining MOSFETs of the dummy cells are unselected.

20. The read circuitry of claim 14, further comprising a reference generator configured to supply the reference signal based on a leakage current and a cell reference current to the sense amplifier.
